(19) United States
(12) Patent Application Publication
(10) Pub. No.: US 2006/0231238 A1
(43) Pub. Date: Oct. 19, 2006

(54) Integrated thermal exchange systems and methods of fabricating same

(75) Inventor: James Clayton Ball JR., Newport News, VA (US)

Correspondence Address: NIXON & VANDERHYE, PC, 901 NORTH GLEBE ROAD, 11TH FLOOR, ARLINGTON, VA, 22203, US

(73) Assignee: PAR Technologies, LLC, Hampton, VA (US)

(21) Appl. No.: 11/104,668

(22) Filed: Apr. 13, 2005

(51) Int. Cl. H05K 7/20

(52) U.S. Cl. 165/104.33; 165/80.4; 361/699

(57) ABSTRACT

Thermal exchange systems integrate a thermal transfer unit (22); a fluid cooling assembly (24); a pump (26); and a fan (28). The thermal transfer unit (22) interfaces with a body to be thermally conditioned and transfers thermal energy to a fluid. The fluid cooling assembly (24) cools the fluid obtained from the thermal transfer unit. The fan (28) directs air around the fluid cooling assembly (24). The pump (26) circulates fluid in a circuit comprising the pump (26), the fluid cooling assembly (2), and the thermal transfer unit (22). In one aspect of integrated system technology, the fan (28) and the circuit are compactly arranged and substantially situated entirely within a footprint (33) of a module housing (30). As another technological aspect, the fluid cooling assembly (24) comprises plural thermal dissipation plates (45) which are laminated together. In an example, non-limiting mode, the plural thermal dissipation plates (45) have features formed thereon by etching or stamping. Such features which may be etched or stamped can include one or more of an aperture (53/64) for defining a fluid inlet channel; a fluid return aperture (55); a thermal dissipation fin (67); a fluid return region (65) which is substantially surrounded by a lamination contact surface through which the thermal dissipation plate (45) is in contact with an adjacent thermal dissipation plate.

### BACKGROUND

1. Field of the Invention

The present invention pertains to compact yet efficient thermal or heat exchange systems.

2. Related Art and Other Considerations

Thermal exchange systems typically have a loop through which a thermally conductive fluid flows. The loop usually includes a heat exchanger; a thermal transfer unit or device in contact with a body or substance to be cooled, and a pump for pumping the thermally conductive fluid between the heat exchanger and the thermal transfer unit.

In many applications the heat exchanger and thermal transfer unit may be located at considerable distance from one another. Yet some applications or environments which require thermal treatment using such a loop have limited space. For example, the cooling of electronic or electrical components of devices such as computers and peripherals should be achieved within the relatively small chassis or frame of the device.

What is needed, therefore, and an object of the present invention, are relatively compact and yet efficient systems for performing thermal transfer for cooling components located in a small, confined volume, and methods for making such systems.

### BRIEF SUMMARY

Thermal exchange systems integrate a thermal transfer unit; a fluid cooling assembly; a fan; and a pump. The thermal transfer unit interfaces with a body to be thermally conditioned and transfers thermal energy to a fluid. The fluid cooling assembly cools the fluid obtained from the thermal transfer unit. The fan directs air around (e.g., toward or away from) the fluid cooling assembly. The pump circulates fluid in a circuit comprising the pump, the fluid cooling assembly, and the thermal transfer unit.

In one aspect of integrated system technology, the fan and the circuit are compactly arranged and substantially situated entirely within a footprint of a module housing. The module housing can be, in an example implementation, a housing, casement, or mount for the fan, e.g., a standard fan for cooling an electronics device such as a computer, for example. The constituent units of the fan, the pump, the fluid cooling assembly, and the thermal transfer unit are stacked together in this order with each constituent unit being directly connected to an adjacent constituent unit without the use of hoses and the like.

As another technological aspect, the fluid cooling assembly comprises plural thermal dissipation plates which are laminated together. In an example, non-limiting mode, the plural thermal dissipation plates have features formed thereon by etching or stamping. Such features which may be etched or stamped can include one or more of the following: a central aperture (for conveying fluid or accommodating a sleeve through which fluid is conveyed); a fluid return aperture; a thermal dissipation fin; a fluid return region which is substantially surrounded by a lamination rim through which the thermal dissipation plate is in contact with an adjacent thermal dissipation plate.

Each of the plural thermal dissipation plates is formed with a lamination contact surface. The plural thermal dissipation plates are stacked in parallel planes with a lamination agent positioned on the lamination contact surfaces between adjacent ones of the plural thermal dissipation plates. The lamination agent is a curable material which, when cured, facilitates formation of a modular fluid cooling assembly.

In one of its aspects, the fluid cooling assembly is arranged so that collectively the plural thermal dissipation plates accommodate or define a fluid inlet channel for conveying fluid from the pump to the thermal transfer unit and separately define a fluid return path for conveying fluid from the thermal transfer unit to the pump. Each of the plural thermal dissipation plates has a central aperture, with the central apertures of the plural thermal dissipation plates being aligned for conveying fluid or accommodating a sleeve (fluid inlet channel) through which fluid is conveyed from the pump to the thermal transfer unit. The fluid inlet channel extends essentially perpendicularly to parallel planes in which each of the plural thermal dissipation plates substantially lie.

In another of its aspects, the fluid cooling assembly is arranged so that each of the plural thermal dissipation plates has a fluid return region. The fluid return region comprises a plate floor or chamber floor which is substantially surrounded by a lamination rim. The thermal dissipation plate is in contact with an adjacent thermal dissipation plate through its lamination rim. A fluid return aperture is formed in the plate floor. The lamination rim can serve as the lamination contact surface which hosts the aforementioned curable lamination agent.

In another of its aspects, the fluid cooling assembly is arranged so that, for two adjacent thermal dissipation plates, the fluid return apertures are not aligned in a direction perpendicular to a plane of the thermal dissipation plates.

In another of its aspects, the fluid cooling assembly is arranged so that each of the plural thermal dissipation plates has plural fluid return regions.

In another of its aspects, the fluid cooling assembly is arranged so that each laminated plate further comprises a thermal dissipation fin which extends laterally with respect to at least one of the plural fluid return regions. The fan directs air around (e.g., toward or away from) the thermal dissipation fins of the fluid cooling assembly. In an example implementation, each laminated plate has an equal number of thermal dissipation fins and plural fluid return regions, with each laminated plate having thermal dissipation fins which contacts two adjacent fluid return regions. For example, the equal number of thermal dissipation fins and plural fluid return regions may be four.

In another of its aspects, the fluid cooling assembly comprises plural types of thermal dissipation plates. The plural types of dissipation plates are alternately arranged in a laminated stack to provide a non-linear fluid return path to the pump. For example, a first type thermal dissipation plate and a second type thermal dissipation plate may be alternately arranged in the laminated stack to provide the non-linear fluid return path to the pump.

In another of its aspects, the fluid cooling assembly thermally isolates the thermal transfer unit from a remainder of the circuit. For example, at least a portion of the fluid cooling assembly can be formed from a thermally non-conductive material. In an embodiment in which the fluid cooling assembly comprises plural thermal dissipation plates which are laminated together, the one of the plural thermal dissipation plate(s) which is in contact with the thermal transfer unit can be formed from a thermally non-conductive material, e.g., a ceramic or plastic.

In an example, non-limiting implementation, the pump comprises a pump housing and a piezoelectric diaphragm which serves as an actuator for the pump.

In example, non-limiting implementation, the thermal transfer unit can comprise a thermal transfer surface for interfacing with a body to be thermally conditioned and a thermal transfer mesh for transferring thermal energy between the thermal transfer surface and the fluid. The thermal transfer mesh is comprised of, e.g., wires or expanded metal which are configured into a mesh, a fluid-porous metallic wool, or a similar structure. In some embodiments, the thermal transfer mesh comprises woven wires, and particularly woven wires which are fused by diffusion bonding into a mesh. In the example implementation, one of the plural thermal dissipation plates can serve as a housing for at least partially enclosing the thermal transfer mesh.

A method of making a thermal exchange system comprises laminating the plural thermal dissipation plates for forming a fluid cooling assembly, and then connecting the fluid cooling assembly between a pump and a thermal transfer unit for forming a fluid circuit.

As one of its aspects, the method can further include etching or stamping a feature on the plural thermal dissipation plates. The etched feature can be one or more of a central aperture; a fluid return aperture; a thermal dissipation fin; a fluid return region which is substantially surrounded by a lamination rim through which the thermal dissipation plate is in contact with an adjacent thermal dissipation plate.

As another of its aspects, the method can further include forming each of the plural thermal dissipation plates with a lamination contact surface, stacking the plural thermal dissipation plates in parallel and with a lamination agent positioned on the lamination contact surfaces of the plural thermal dissipation plates, and then curing the lamination agent to form a modular fluid cooling assembly

### BRIEF DESCRIPTION OF THE DRAWINGS

The foregoing and other objects, features, and advantages of the invention will be apparent from the following more particular description of preferred embodiments as illustrated in the accompanying drawings in which reference characters refer to the same parts throughout the various views. The drawings are not necessarily to scale, emphasis instead being placed upon illustrating the principles of the invention.

FIG. 1 is a top isometric view of an integrated thermal exchange module according to a first example embodiment.

FIG. 2 is a cross sectioned isometric view of the integrated thermal exchange module of FIG. 1.

FIG. 3 is a cross sectioned isometric view of the integrated thermal exchange module of FIG. 1 with a fan removed.

FIG. 4 is a cross sectioned isometric view of the integrated thermal exchange module of FIG. 1 with a fan and fan mounting bracket removed.

FIG. 5 is an exploded view of the integrated thermal exchange module of FIG. 1.

FIG. 6 is a cross sectioned isometric view of selected components of the integrated thermal exchange module of FIG. 1, the selected components including a thermal transfer unit and an anchor portion of a fluid cooling assembly.

FIG. 7A is a top isometric view of a first type of thermal dissipation plate included in a fluid cooling assembly of the integrated thermal exchange module of FIG. 1.

FIG. 7B is a rear isometric view of the first type of thermal dissipation plate of FIG. 7A.

FIG. 8A is a top isometric view of a second type of thermal dissipation plate included in a fluid cooling assembly of the integrated thermal exchange module of FIG. 1.

FIG. 8B is a rear isometric view of the second type of thermal dissipation plate of FIG. 8A.

FIG. 9 is a cross sectioned isometric view of plural thermal dissipation plates of a fluid cooling assembly.

FIG. 10 is a cross sectioned exploded isometric view of a pump of the integrated thermal exchange module of FIG. 1.

### DETAILED DESCRIPTION OF THE DRAWINGS

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. In other instances, detailed descriptions of well-known devices, circuits, and methods are omitted so as not to obscure the description of the present invention with unnecessary detail.

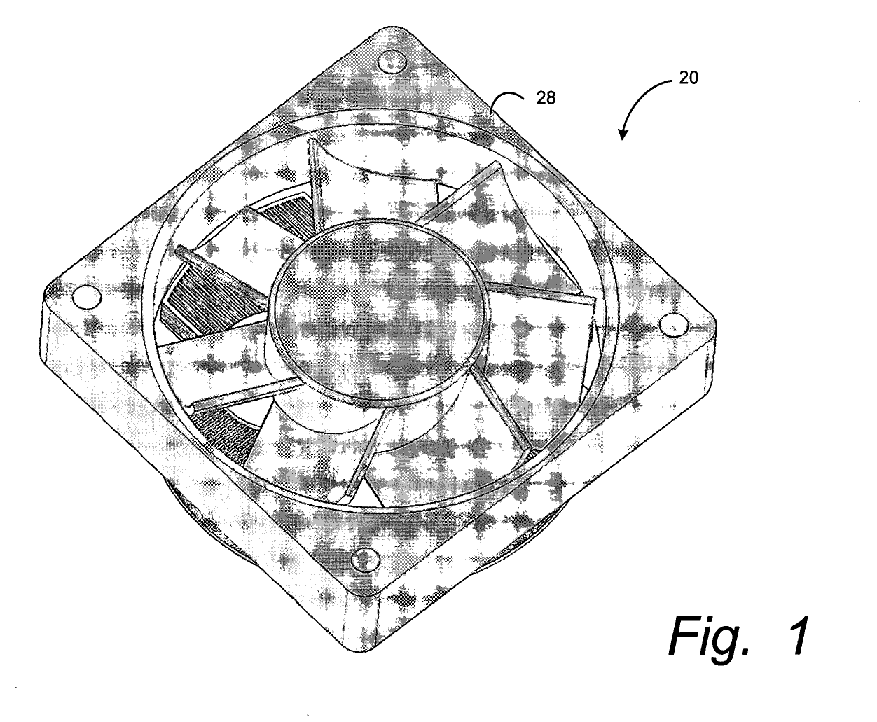

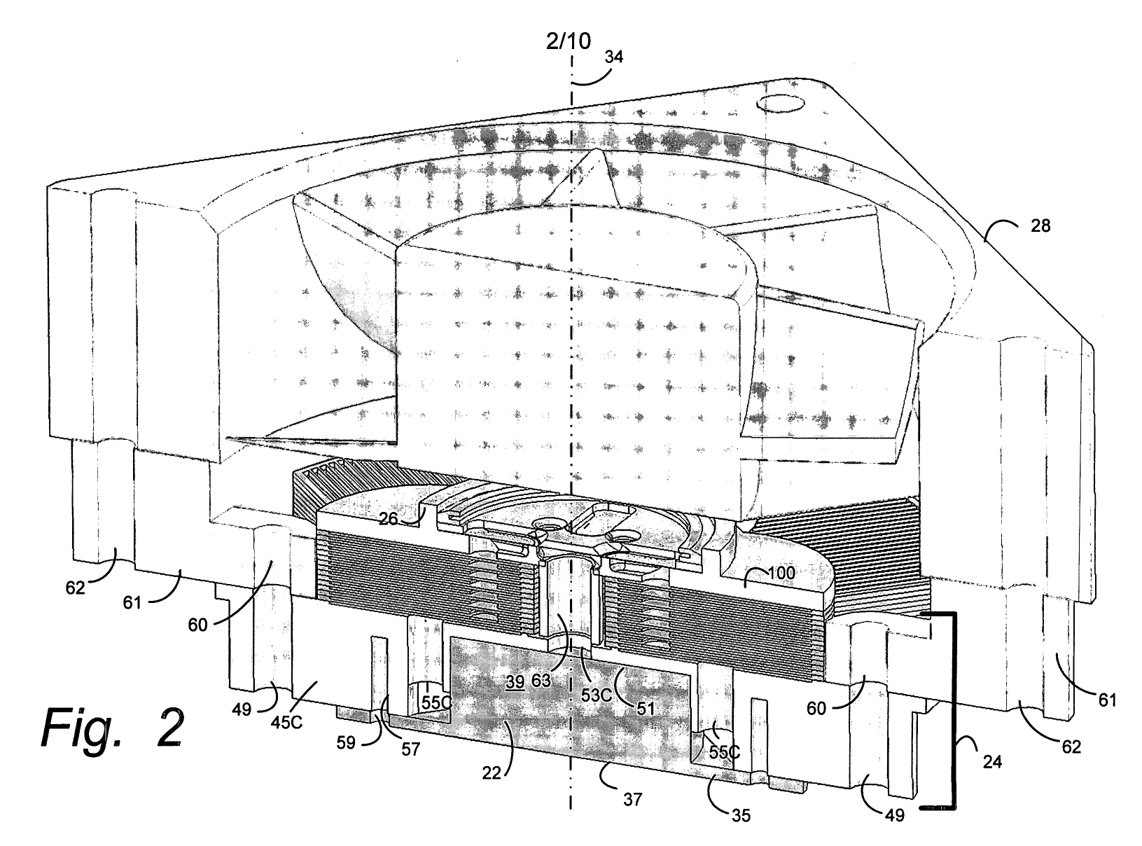

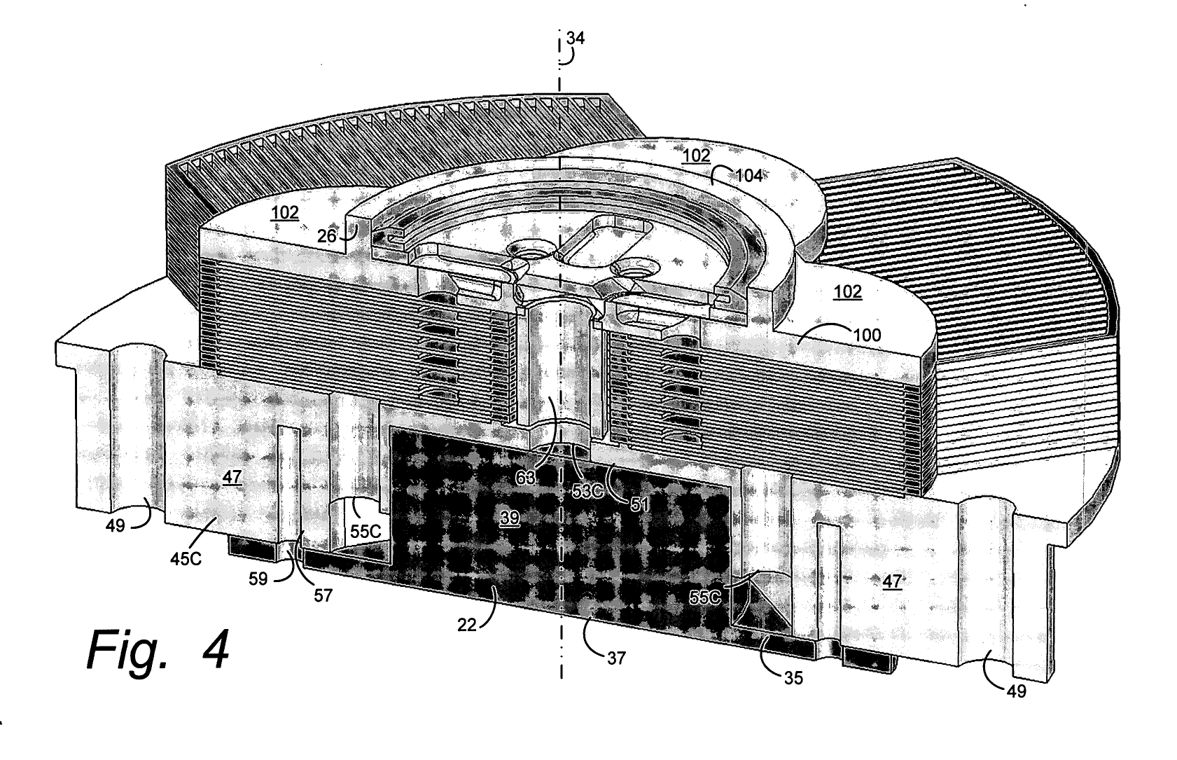

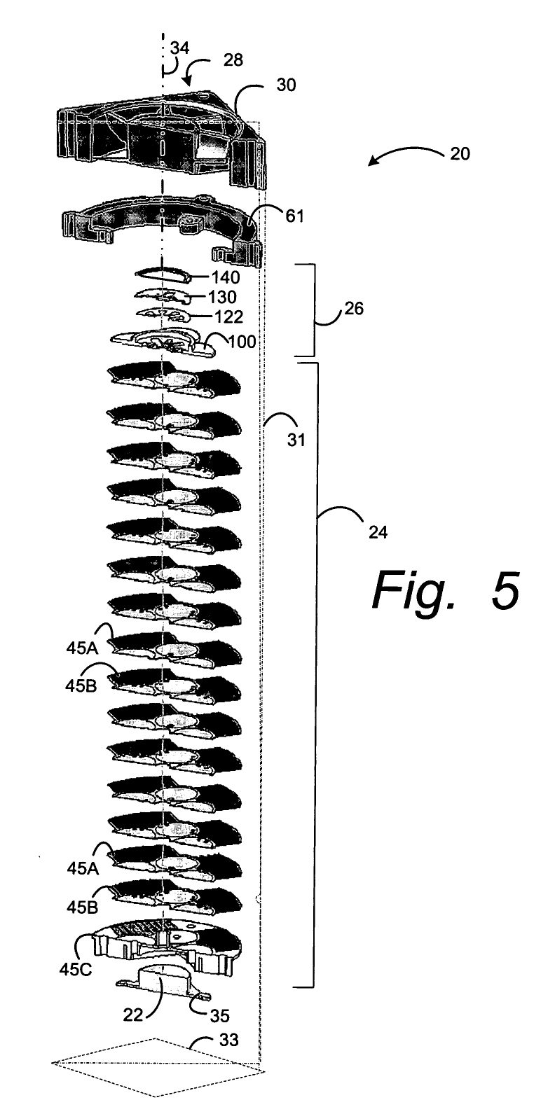

FIG. 1-FIG. 4 show an integrated thermal exchange module 20 according to an example embodiment. FIG. 1 shows thermal exchange module 20 from its top, while FIG. 2-FIG. 4 show cross sectioned views of some or (in the case of FIG. 2) all constituent units of the thermal exchange module 20. FIG. 5 provides an exploded depiction of constituent units comprising thermal exchange module 20. The constituent units which are integrated into thermal exchange module 20 include a thermal transfer unit 22; a fluid cooling assembly 24; a pump 26; and, a fan 28.

In general, and as shown in FIG. 2-FIG. 6, thermal transfer unit 22 interfaces with a body to be thermally conditioned and transfers thermal energy to a fluid. For example, the thermal transfer unit 22 can have a flat surface or the like which is situated on or mounted to a body to be thermally conditioned. Fluid cooling assembly 24 (see FIG. 5) cools the fluid obtained from thermal transfer unit 22. Fan 28 directs air around (e.g., toward or away from) fluid cooling assembly 24. Pump 26 circulates fluid in a fluid circuit, the fluid circuit comprising pump 26, the fluid cooling assembly 24, and thermal transfer unit 22.

The body to be thermally conditioned can be any device requiring cooling (or, conversely, heating). Examples of such bodies or devices include electronic components such as, for example, microprocessors. Typically these bodies or devices are situated in relatively small chassis or frames, such as a computer or laptop case, for example. Accordingly, in a first non-limiting example embodiment, fan 28 and the constituent units which form the circuit are compactly arranged and substantially situated entirely within a footprint of a module housing. As used herein, “footprint” refers to a projection of an outer perimeter of the module housing on a plane (e.g., a plane perpendicular to an axis of rotation of fan 28). “Substantially situated entirely within” refers to the fact that projections of perimeters of the constituent units on the plane lie substantially within the projection of the outer perimeter of the module housing.

The module housing can be, in an example implementation, a housing, casement, or mount for the fan. For example, FIG. 1-FIG. 5 show the module housing as being a housing 30 for fan 28. Preferably but not necessarily, the fan 28 is a standard commercial fan for cooling an electronic device such as a computer or laptop, for example. The fan 28 with its module housing 30 could alternatively be customized for a particular application. The module housing could be a casement or frame other than a fan housing, so long as (for this particular example aspect) the aforementioned constituent units are substantially situated entirely within its footprint. Moreover, the footprint of the module housing can encompass constituent units for plural thermal exchange circuits. In other aspects or embodiments, the module housing could even extend over or encompass other constituent units accommodating or defining plural fluid circuits.

In FIG. 5, dot-dashed lines 31 represent projection lines for module housing 30. The footprint for module housing 30 is depicted by broken line footprint 33. Projections of perimeters of thermal transfer unit 22, fluid cooling assembly 24, and pump 26 are substantially situated entirely within footprint 33.

The constituent units of fan 28, pump 26, fluid cooling assembly 24, and thermal transfer unit 22 are stacked together, in this order and in an axial direction, with each constituent unit being directly connected to an adjacent constituent unit without the use of hoses and the like. “Axial direction” refers to the axis of rotation 34 about which the blades of fan 28 rotate, which is also parallel to the direction of fluid flow from pump 26 to thermal transfer unit 22.

In the example implementation shown in more detail in FIG. 2-FIG. 6, thermal transfer unit 22 comprises a thermal transfer plate 35 having a thermal transfer surface 37 and a thermal transfer mesh 39. The thermal transfer surface 37 serves to interface with, e.g., contact, the body to be thermally conditioned. Preferably the thermal transfer surface 37 has a planar configuration, so that the body or device to be thermally conditioned can be situated on or in contact with thermal transfer surface 37. As mentioned before, the body or device to be thermally conditioned can be a microprocessor or other thermally sensitive electronic component.

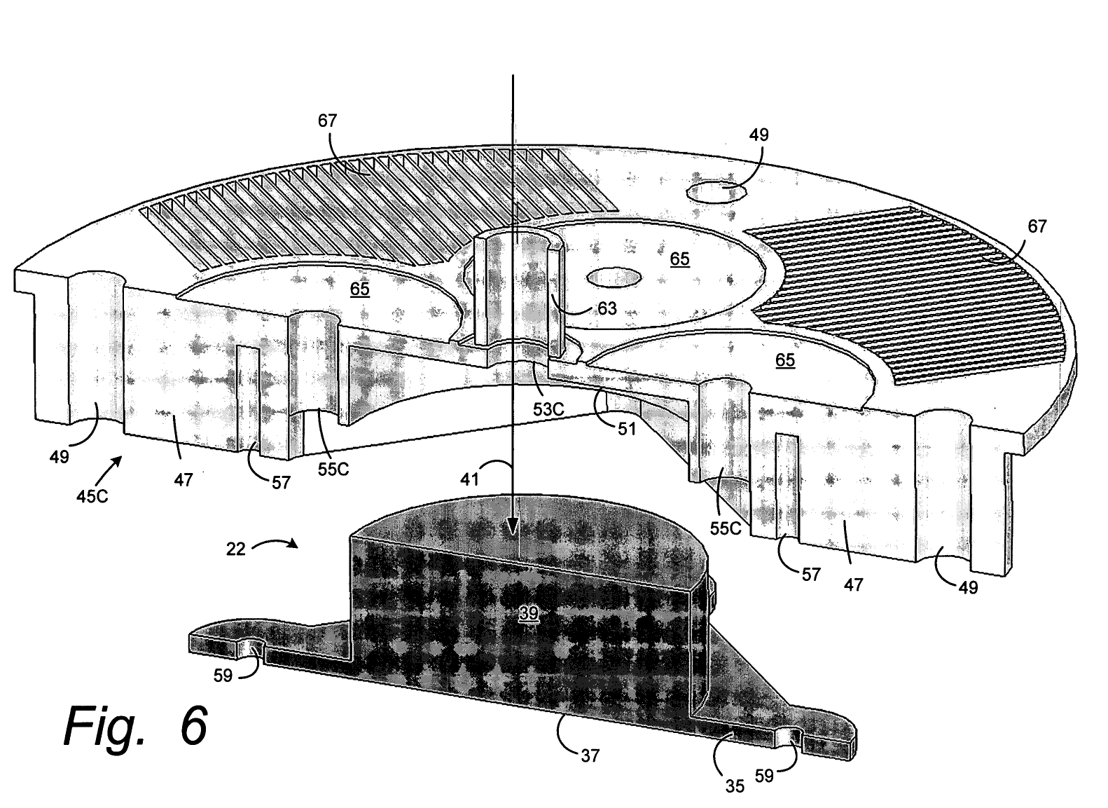

On a portion or surface of thermal transfer plate 35 which is opposite thermal transfer surface 37, the thermal transfer plate 35 bears or has positioned or mounted thereon the thermal transfer mesh 39. As an example, thermal transfer mesh 39 may be configured in an essentially cylindrical or annular configuration. Thermal transfer mesh 39 serves for transferring thermal energy between the thermal transfer surface and the fluid. In particular, fluid supplied to thermal transfer unit 22 (in the direction depicted by fluid flow arrow 41 in FIG. 6) is centrally incident upon thermal transfer mesh 39, and flows through interstices or the like provided in thermal transfer mesh 39. In passing through the thermal transfer mesh 39, the fluid picks up or absorbs thermal energy (e.g., heat) which has been absorbed by thermal transfer plate 35 from the body to be thermally conditioned. Eventually the fluid travels in an outward direction (e.g., a radial direction with respect to a cylindrical mesh) and travels to fluid cooling assembly 24.

The thermal transfer mesh can be comprised of, e.g., wires or expanded metal which are configured into a mesh, a fluid-porous metallic wool, or a similar structure. In some embodiments, the thermal transfer mesh comprises woven wires, and particularly woven wires which are fused by diffusion bonding into a mesh. Various examples constructions for thermal transfer mesh 39 are understood from U.S. patent application Ser. No. 11/025,845, filed Dec. 31, 2004, which is incorporated by reference in its entirety. The thermal transfer mesh 39 can be integrally formed, welded, or otherwise attached to thermal transfer plate 35.

As one independent aspect of this thermal exchange system technology, fluid cooling assembly 24 can comprise plural thermal dissipation plates 45. Preferably the plural thermal dissipation plates 45 are laminated together to form a dissipation plate stack. FIG. 5 shows three basic types of thermal dissipation plates 45 comprising the dissipation plate stack: thermal dissipation plate 45A, thermal dissipation plate 45B, and thermal dissipation plate 45C. While preferably the stack comprises plural thermal dissipation plates 45A and plural thermal dissipation plates 45B, alternately arranged as hereinafter described, the stack has only one thermal dissipation plate 45C. The one thermal dissipation plate 45C serves as a base or anchor thermal dissipation plate or member.

The thermal dissipation plate 45C is illustrated in FIG. 2 and FIG. 5 and particularly in more detail in FIG. 6. The thermal dissipation plate 45C resembles thermal dissipation plate 45A in having an essentially planar plate, but basically differs from thermal dissipation plate 45A by having foundational walls 47 (extending rearwardly or downwardly from the planar plate) with attachment apertures 49 extending therethrough. The foundational walls 47 are preferably shaped, configured, or arranged to form a compartment or enclosure for thermal transfer mesh 39. In the example illustrated implementation, the foundational walls 47 form a square or other quadrilateral. A mesh compartment roof 51 formed on an underside of the planar plate of thermal dissipation plate 45C may be contoured to accommodate thermal transfer mesh 39, particularly when (as in the illustrated example) the thermal transfer mesh 39 has a non-quadrilateral shape (such as a cylinder). Preferably thermal transfer mesh 39 is situated centrally within the compartment bounded by foundational walls 47. The mesh compartment roof 51 of thermal dissipation plate 45C has a fluid inlet aperture 53C preferably centrally formed therein. In addition, one or more fluid return apertures 55C are formed through the planar plate of thermal dissipation plate 45C, the fluid return apertures 55C being strategically positioned around the chamber occupied by thermal transfer mesh 39 so that fluid exiting thermal transfer mesh 39 can be directed into fluid cooling assembly 24 through the fluid return apertures 55C. In the illustrated example implementation, four such fluid return apertures 55C are provided, one in each corner of the mesh compartment defined by foundational walls 47. As apparent from the foregoing, as used herein “fluid inlet aperture” refers to fluid flow in a direction from pump 26 to thermal transfer unit 22, while “fluid return aperture” refers to fluid flow in a direction from thermal transfer unit 22 to pump 26, e.g., fluid return to pump 26.

Thus, the foundation walls 47 of anchor thermal dissipation plate 45C define a cavity for accommodating thermal transfer mesh 39. Proximate the corners of the cavity the foundational walls 47 have anchor holes 57. The anchor holes 57 (which may be threaded) are configured to receive shafts of fasteners which secure thermal transfer plate 35 to the underside of anchor thermal dissipation plate 45C. The anchor holes 57 are aligned with fastener apertures 59 formed proximate corners of thermal transfer plate 35. The attachment apertures 49 can each be threaded or otherwise journaled for accommodating fasteners such as screws or bolts, for example. The attachment apertures 49 are aligned with corresponding apertures 60 in fan mounting bracket 61.

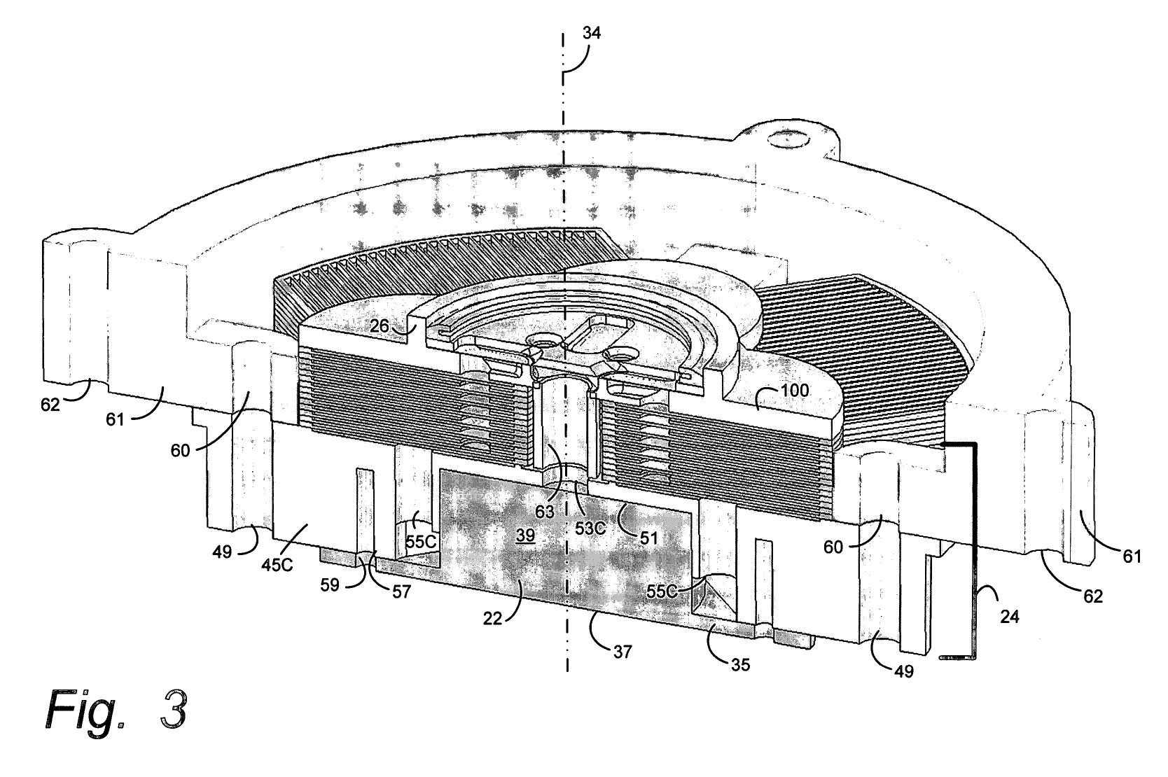

The fan mounting bracket 61 is shown in FIG. 2 and FIG. 3 as surrounding portions of fluid cooling assembly 24 which are situated above anchor thermal dissipation plate 45C. As such fan mounting bracket 61 has an outer perimeter which is essentially shaped as a quadrilateral (preferably of approximately the same perimeter as fan 28 and/or module housing 30) and interior cavity (preferably circular) for accommodating fluid cooling assembly 24. The fan mounting bracket 61 has fan mount apertures 62 which accommodate a fastener or the like which secures fan 28 to fan mounting bracket 61.

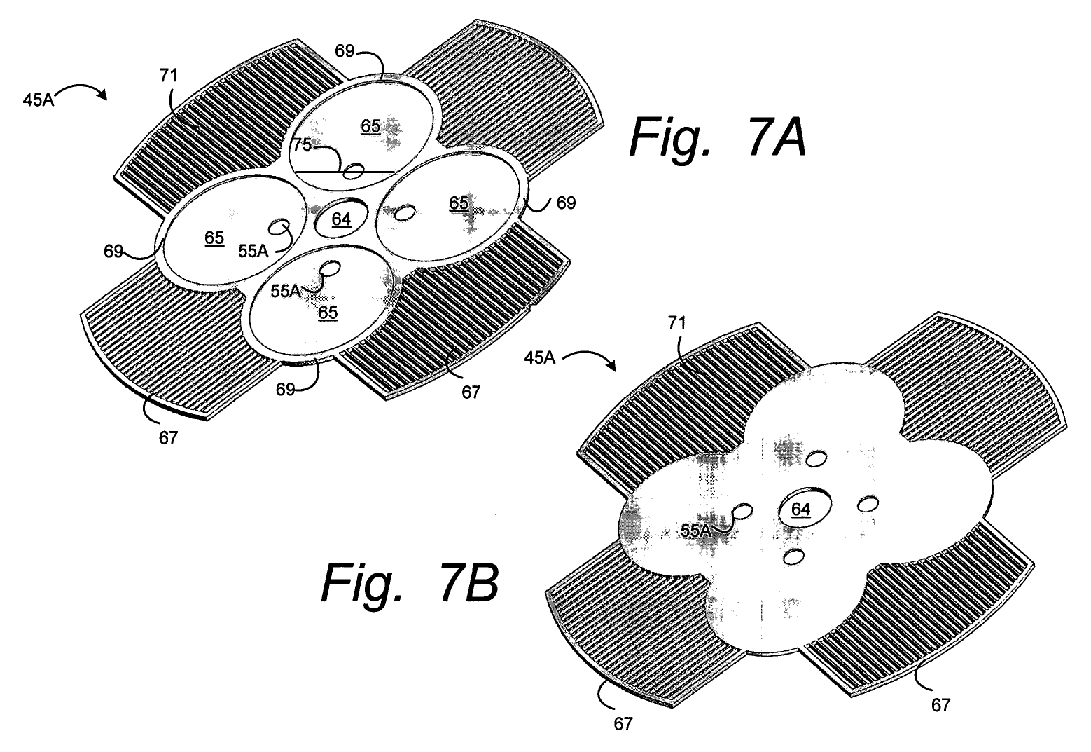

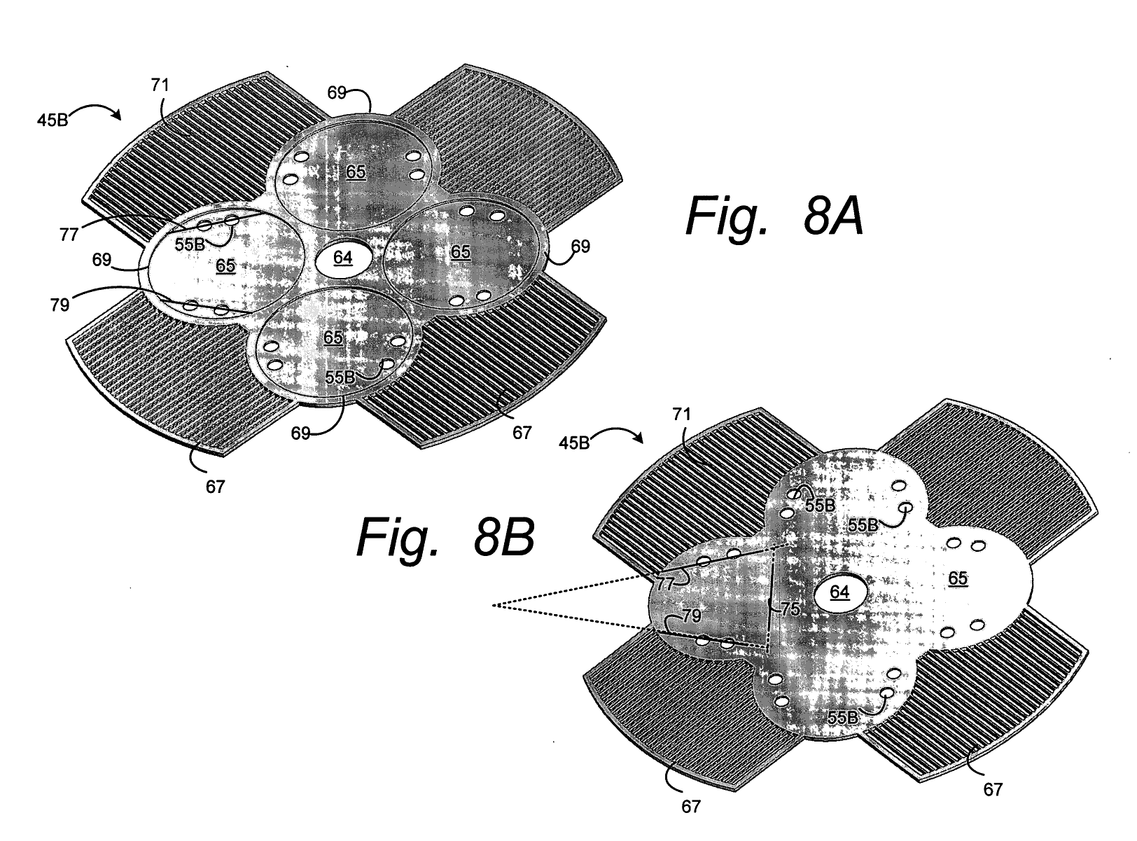

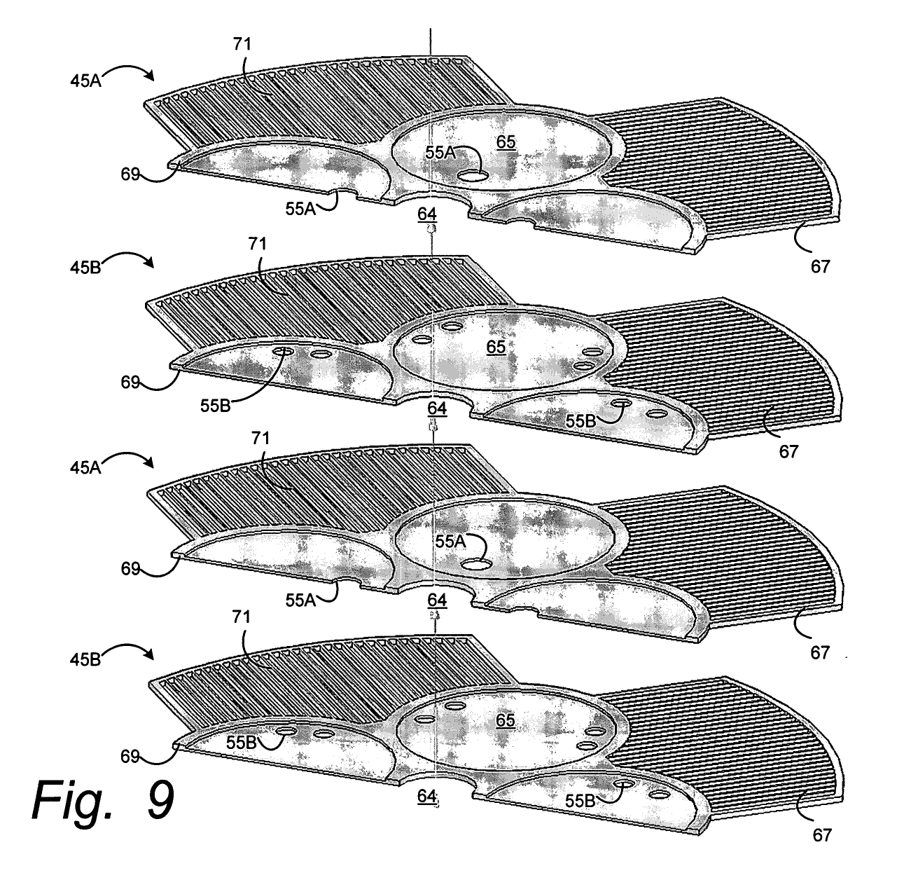

The thermal dissipation plate 45C further differs from thermal dissipation plate 45A in having, on its top surface, a hollow cylindrical alignment sleeve 63. The alignment sleeve 63 extends essentially perpendicularly from the plane of thermal dissipation plate 45C, e.g., parallel to the axial direction. The thermal dissipation plates 45A and thermal dissipation plates 45B instead have sleeve apertures 64 centrally formed therein so that the thermal dissipation plates 45A (see FIG. 7A and FIG. 7B) and thermal dissipation plates 45B (see FIG. 8A and FIG. 8B) can fit over the cylindrical alignment sleeve 63.

Regardless of type, the thermal dissipation plates 45 each have certain common features formed thereon. The common features for the thermal dissipation plates 45 include one or more fluid return regions 65; one or more fluid return apertures 55 formed in each fluid return region 65; and, one or more thermal dissipation fins 67 (see, e.g. FIG. 7A and FIG. 7B for thermal dissipation plates 45A, and FIG. 8A and FIG. 8B for thermal dissipation plates 45B). Each fluid return region 65 is substantially surrounded by, and in a sense defined by, a lamination rim 69. In the illustrated implementation, the fluid return regions 65 are illustrated as circular depressed planar regions, with other geometrical shapes being possible. As explained herein, the fluid return region 65 thus forms a planar disk-shaped channel through which fluid flows when returning from thermal transfer unit 22 to pump 26. In other example implementations, fluid return regions 65 may be configured with a different geometrical shape.

It is preferably through the lamination rims 69 of the various fluid return regions 65 by which a thermal dissipation plate comes into contact and bonds with an adjacent thermal dissipation plate. In this regard, the lamination rims 69 are formed on an upperside of each planar plate portion of a thermal dissipation plate 45, and abut essentially flat undersides of thermal dissipation plates 45A (see FIG. 7B) and thermal dissipation plates 45B (see FIG. 8B). In fabricating the fluid cooling assembly 24, an unillustrated lamination agent is inserted between the abutment of a lamination rim 69 and the underside of a superiorly positioned thermal dissipation plate 45.

The lamination rims 69 thus serve as one non-limiting example of a lamination contact surface. The plural thermal dissipation plates 45 are stacked in parallel planes with the lamination agent positioned on the lamination contact surface(s) between adjacent ones of the plural thermal dissipation plates. The lamination agent is a curable material which, when cured, facilitates formation of a modular fluid cooling assembly 24. The lamination agent can be can substance or material which, when cured, forms a strong, fluid-tight bond between adjacent thermal dissipation plates 45. The choice of lamination agent depends on the choice of materials for the thermal dissipation plates 45. In an example implementation in which the thermal dissipation plates 45 are formed of copper or other thermally conductive metal, the lamination agent can be a film such as polyimide, for example.

As another independent aspect of fluid cooling assembly 24, and in an example, non-limiting mode, one or more of the features of the plural thermal dissipation plates 45 are formed by etching, e.g., chemical etching or stamping. Such features which may be etched or stamped can include one or more of the sleeve apertures 64; fluid return aperture(s) 55; louvers 71 in the thermal dissipation fins 67; and, the planar channels of the fluid return regions 65 (thus providing the lamination rims 69). These features may be formed by any suitable chemical etching process, such as a process which uses one or more of Hydrochloric Acid (HCI), Phosphoric Acid (H3PO4), Sodium Hydroxide (NaOH) and Sulfuric Acid (H2SO4) as an etchant (when etching thermal dissipation plates 45 formed from copper). One or more etching operations may be performed for each thermal dissipation plate 45, depending on depth of etch required for each feature.

The fluid cooling assembly 24 is arranged so that collectively the plural thermal dissipation plates 45 define a channel for sleeve 63 through which fluid is conveyed from pump 26 to thermal transfer unit 22, and separately define a fluid return path for conveying fluid from thermal transfer unit 22 to pump 26. Each of the plural thermal dissipation plates 45 has a central aperture through which fluid is conveyed toward thermal transfer unit 22, the central aperture either accommodating sleeve 63 in the case of thermal dissipation plates 45A and thermal dissipation plates 45B, or the aperture essentially receiving the fluid from sleeve 63 in the case of anchor thermal dissipation plate 45C. The apertures 64 and 53 of the plural thermal dissipation plates 45 are thus aligned to form a fluid inlet channel for communicating the fluid from pump 26 to thermal transfer unit 22. The fluid inlet channel extends essentially perpendicularly to parallel planes in which each of the plural thermal dissipation plates substantially lie.

Preferably each of the plural thermal dissipation plates 45 has plural fluid return regions 65. Further, the fluid inlet channel formed by the sleeve apertures 64 and fluid inlet aperture 53 is positioned centrally with respect to the plural fluid return regions 65 arranged thereabout. In the example illustrated implementation, each thermal dissipation plate 45 has four fluid return regions 65 arranged about its central aperture 53 or 64. A greater or lesser (e.g., three) number of fluid return regions 65 may instead be provided for each thermal dissipation plate 45.

The fluid cooling assembly is arranged so that each laminated plate further comprises the thermal dissipation fin 67 which extends laterally with respect to at least one of the plural fluid return regions 65. The fan 28 directs air around (e.g., toward or away from) thermal dissipation fins 67 of the fluid cooling assembly 24, so that air travels through the louvers 71 formed entirely through each lamination rim 67. In the example illustrated implementation, each laminated plate 45 has an equal number of thermal dissipation fins 67 and plural fluid return regions 65, with each laminated plate 45 having thermal dissipation fins 67 which contacts or borders at least portions of the perimeters of two adjacent fluid return regions 65. For example, the equal number of thermal dissipation fins 67 and plural fluid return regions 65 may be four, as in the example illustrated implementation.

As mentioned above, fluid cooling assembly 24 comprises plural types of thermal dissipation plates 45. The plural types of dissipation plates 45 are alternately arranged in a laminated stack to provide a non-linear fluid return path to the pump. For example, the first type thermal dissipation plate 45A and the second type thermal dissipation plate 45B may be alternately arranged in the laminated stack to provide the non-linear fluid return path to pump 26. For example, FIG. 5 shows thermal dissipation plate 45B (second type) being positioned on the one foundational thermal dissipation plate 45C, with thermal dissipation plate 45A (first type) being positioned over thermal dissipation plate 45B. FIG. 5 further shows that the alternating sequence continues with thermal dissipation plate 45B, thermal dissipation plate 45A, thermal dissipation plate 45B, and so forth. The number of thermal dissipation plates 45, and thus the height of the stack of plates forming fluid cooling assembly 24, can be selected or determined by or in accordance with the degree of thermal treatment required and/or the volume/capacity of space into which the thermal exchange module 20 is to be disposed.

As described previously, in fluid cooling assembly 24 each of the plural thermal dissipation plates 45 has a fluid return region 65. The fluid return region 65 comprises a plate floor or chamber floor which is substantially surrounded by the lamination rim 69. One or more fluid return apertures 55 is/are formed in the plate floor. The fluid cooling assembly 24 is arranged so that, for two adjacent thermal dissipation plates, the fluid return apertures 55 are not aligned in a direction perpendicular to a plane of the thermal dissipation plates, e.g., not aligned in the axial direction.

In the above regard, the first thermal dissipation plate 45A illustrated in more detail in FIG. 7A and FIG. 7B. For each fluid return region 65, the first thermal dissipation plate 45A has one fluid return aperture 55A which is located so as to have circle chord 75 extend through its diameter (see FIG. 7A). On the other hand, the second thermal dissipation plate 45B has two pairs of fluid return apertures 55 for each of its fluid return regions 65. A first pair of fluid return apertures 55 have circle chord 77 extending through both fluid return apertures 55 of the first pair; a second pair of fluid return apertures 55 have chord 79 extending through both fluid return apertures 55 of the second pair. When extended in the manner shown in FIG. 8B, the chords 75, 77 and 79 essentially form a triangle. The offset placement of the fluid return apertures 55 for adjacent, alternating type thermal dissipation plates 45 provides a non-linear, e.g., essentially serpentine return path for return fluid flow from thermal transfer unit 22 to pump 26.

In one example and optional variation, the fluid cooling assembly 24 can serve to thermally isolate thermal transfer unit 22 from a remainder of the fluid circuit. For example, at least a portion of the fluid cooling assembly 24 can be formed from a thermally non-conductive material. In an embodiment in which the fluid cooling assembly comprises plural thermal dissipation plates which are laminated together, the foundational thermal dissipation plate 45C which is in contact with the thermal transfer unit 22 can be formed from a thermally non-conductive material, e.g., a ceramic or plastic.

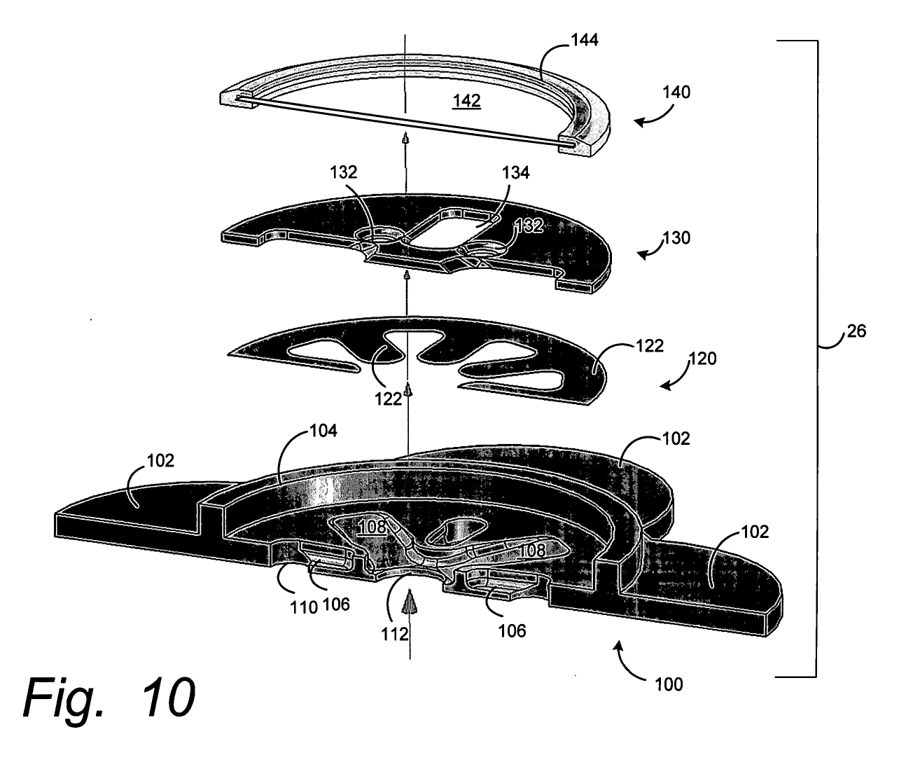

Certain aspects of an example pump 26 for use with the thermal exchange module 20 of FIG. 1 are illustrated in exploded fashion in FIG. 5 and (in more detail) in FIG. 10, and are shown as assembled in FIG. 2-FIG. 4. It should be understood that other pump configurations and architectures are also possible, the FIG. 10 embodiment being just one example.

As shown in enlarged fashion in FIG. 10, pump 26 comprises a pump body plate 100. The pump body plate 100 is essentially planar, appearing as with an essentially clover leaf shape from above having four semicircular leaves 102. The semicircular leaves 102 are configured essentially to cover the aligned fluid return regions 65 of the underlying thermal dissipation plates 45.

The pump body plate 100 further has an essentially ring shaped rim 104 centrally provided on its topside for defining a pump chamber, for which reason rim 104 is also known as pump chamber rim 104. Interior of pump chamber rim 104, pump body plate 100 has eight features. Four of the features are fluid return channels 106; four of the features are fluid inlet ramps 108. It should be recalled that, in the sense of the overall fluid circuit, fluid inlet is in the sense of fluid travel from pump 26 to thermal transfer unit 22, while fluid return is in the sense of fluid return from thermal transfer unit 22 to pump 26. Thus, the fluid return channels 106 actually serve to supply fluid to pump 26, while the fluid inlet ramps 108 allow exit of fluid from pump 26.

The fluid return channels 106 communicate with an essentially circular aperture 110 on the bottom side of pump body plate 100 and essentially open into or form an elongated oval trough as seen from the top of pump body plate 100. The four fluid return channels 106 are essentially arranged at ninety degree angles about the center of pump body plate 100. As mentioned above, the fluid return channels 106 are aligned above the fluid return region 65 of the underlying thermal dissipation plates 45.

The fluid inlet ramps 108 each taper in depth toward a center of pump body plate 100. At the center of pump body plate 100 the four fluid inlet ramps 108 collectively empty into pump discharge port 112. The four fluid inlet ramps 108 are arranged at ninety degrees to one another, with each of the fluid inlet ramps 108 being alternately arranged about pump body plate 100 with the four fluid return channels 106. Each fluid inlet ramp 108 is essentially equidistantly/equiangularly located between adjacent fluid return channels 106.

Valve layer 120 overlies the pump body plate 100 interior of the pump chamber rim 104. The valve layer 120 preferably has a perimeter sized to fit snuggly over pump body plate 100 and within pump chamber rim 104. Preferably valve layer 120 is circular or ring shaped and further has a series of valve flaps 122 extending in an interior direction. In the illustrated embodiment, eight valve flaps 122 are provided and are arranged for selectively opening and closing the eight features formed in pump body plate 100, e.g., the four fluid return channels 106 and the four fluid inlet ramps 108. The valve layer 120 is preferably formed from a material or layers of materials that provide sufficient flexibility for responding to fluid actuation in pump 26, but which are also rigid enough so that the valve flaps 122 actually close when required to do so and do not loose character over time. For example, the valve layer 120 can be a three-layered laminate having a central stiffening layer (e.g., metallic layer) and can be structured and/or fabricated in accordance with the teachings of simultaneously filed U.S. patent application Ser. No. 11/______ (attorney docket: 4209-68), entitled “MULTILAYER VALVE STRUCTURES, METHODS OF MAKING, AND PUMPS USING SAME”, which is incorporated by reference herein in its entirety.

A pump chamber floor insert 130 fits snuggly over valve layer 120 in the pump chamber defined by pump chamber rim 104. The pump chamber floor insert 130 is thus also preferably circular in shape, and also has eight fluid flow features provided therein. Four of the fluid flow features defined in pump chamber floor insert 130 are pump exit apertures 132. The four pump exit apertures 132 are essentially circular in shape, and reside over a portion (preferably the highest portion) of corresponding fluid inlet ramps 108. The other four of the fluid flow features defined in pump chamber floor insert 130 are pump inlet cavities 134 which reside over the corresponding fluid return channels 106. The pump inlet cavities 134 have substantially the same trough shape as the fluid return channels 106. Of course, valve flaps 122 extend between the four pump exit apertures 132 and the underlying fluid inlet ramps 108 positioned therebeneath. Similarly, valve flaps 122 extend between the four pump inlet cavities 134 and the fluid return channels 106 positioned therebeneath.

A diaphragm assembly or diaphragm layer 140 fits over the pump chamber floor insert 130 for covering the pump chamber which exists interior of pump chamber rim 104. In one example, non-limiting embodiment, the diaphragm layer comprises a piezoelectric central region 142 which is selectively deformable upon application of an electrical signal for pumping fluid into and out of the pumping chamber. A retaining ring or sealing ring 144 or the like surrounds and engages the piezoelectric central region 142. Diaphragm structures other than piezoelectric diaphragms are also usable for pump 26. In an example embodiment in which the diaphragm happens to be a piezoelectric diaphragm, the diaphragm retaining ring 144 can comprise an electromagnetically transmissive region which essentially surrounds the central piezoelectric region and which is utilized for electromagnetic bonding, as described in simultaneously-filed U.S. patent application Ser. No. 11/______ (attorney docket: 4209-54) entitled “ELECTROMAGNETICALLY BONDED PUMPS AND PUMP SUBASSEMBLIES AND METHODS OF FABRICATION”, which is incorporated herein by reference in its entirety.

The thermal transfer unit for interfacing with a body to be thermally conditioned and for transferring thermal energy to a fluid has herein been illustrated as comprising a thermal transfer mesh or the like. Other embodiments employ other suitable thermal transfer structures. For example, the thermal transfer can take the form of unit, housing, or subassembly in which the body to be thermally conditioned (e.g., electronic chip) is at least partially immersed in a fluid (pumped by the pump of the integrated system) which is electrically non-conductive but thermally conductive.

Moreover, in embodiments in which the diaphragm is a piezoelectric diaphragm, such diaphragms can be constructed in or otherwise be in accord with the teachings of one or more of the following (all of which are incorporated herein by reference in their entirety): PCT patent application PCT/US01/28947, filed 14 Sep. 2001; U.S. patent application Ser. No. 10/380,547, filed Mar. 17, 2003, entitled “Piezoelectric Actuator and Pump Using Same”; U.S. patent application Ser. No. 10/380,589, filed Mar. 17, 2003, entitled “Piezoelectric Actuator and Pump Using Same”; and simultaneously filed U.S. Provisional Patent Application______ (attorney docket: 4209-72), entitled “PIEZOELECTRIC DIAPHRAGM ASSEMBLY WITH CONDUCTORS ON FLEXIBLE FILM”. Of course, as stated previously, the pump 26 need not be a piezoelectric pump, as other types of pumps (diaphragm and non-diaphragm) can be used for thermal exchange module 20.

It should be realized that various technological aspects herein described are independent and need not be utilized in conjunction with various other aspects. For example, one separable and independent aspect is the fact that the constituent elements of the fluid circuit are bounded by the footprint of the module housing. Such bounding within the module housing footprint reflects a modularity and integration which is particularly beneficial. This bounding or containment with the module housing footprint need not require other technological aspects disclosed herein, e.g., need not include the laminated nature of fluid cooling assembly 24, for example.

Similarly, the laminated nature of fluid cooling assembly 24 is another independent technological aspect that is not dependent upon or linked to various other aspects herein disclosed. For example, a laminated fluid cooling assembly 24 may be included in a thermal exchange system in which constituent units are not bounded by a module housing footprint. The lamination of fluid cooling assembly 24 is particularly advantageous as an efficient and expeditious way of fabricating fluid cooling assembly 24.

In the above regard, the foregoing description also reflects basic steps of a method of making a thermal exchange system. Such method comprises a basic step of laminating the plural thermal dissipation plates for forming a fluid cooling assembly, and then a step of connecting the fluid cooling assembly between a pump and a thermal transfer unit for forming a fluid circuit.

As another separable and independent aspects, in conjunction with the laminating of the fluid cooling assembly 24 or in conjunction with methods for forming fluid cooling assembly 24 by non-lamination techniques, the thermal dissipation plates 45 can easily be formed by etching or stamping. In this regard, methods of making the thermal exchange module or system can include etching or stamping a feature on the plural thermal dissipation plates. The etched or stamped feature can be one or more of a central aperture; a fluid return aperture; a thermal dissipation fin; a fluid return region which is substantially surrounded by a lamination rim through which the thermal dissipation plate is in contact with an adjacent thermal dissipation plate.

As another of its aspects, the method can further include forming each of the plural thermal dissipation plates with a lamination contact surface, stacking the plural thermal dissipation plates in parallel and with a lamination agent positioned on the lamination contact surfaces of the plural thermal dissipation plates, and then curing the lamination agent to form a modular fluid cooling assembly

Although various embodiments have been shown and described in detail, the claims are not limited to any particular embodiment or example. None of the above description should be read as implying that any particular element, step, range, or function is essential such that it must be included in the claims scope. The scope of patented subject matter is defined only by the claims. The extent of legal protection is defined by the words recited in the allowed claims and their equivalents. It is to be understood that the invention is not to be limited to the disclosed embodiment, but on the contrary, is intended to cover various modifications and equivalent arrangements.

What is claimed is:

1. An integrated thermal exchange module comprising:
a module housing;
a thermal transfer unit for interfacing with a body to be thermally conditioned and for transferring thermal energy to a fluid;
a fluid cooling assembly for cooling the fluid obtained from the thermal transfer unit;
a fan for directing air around the fluid cooling assembly;
a pump for circulating fluid in a circuit comprising the pump, the thermal transfer unit, and the fluid cooling assembly;
wherein the fan and the circuit substantially are situated entirely within a footprint of the module housing.

2. The apparatus of claim 1, wherein the module housing is a housing for the fan.

3. The apparatus of claim 1, wherein the thermal transfer unit comprises:
a thermal transfer surface for interfacing with a body to be thermally conditioned; and
a thermal transfer mesh for transferring thermal energy between the thermal transfer surface and the fluid.

4. The apparatus of claim 3, wherein the fluid cooling assembly comprises plural thermal dissipation plates which are laminated together, wherein one of the plural thermal dissipation plates serves as a housing for at least partially enclosing the thermal transfer mesh.

5. The apparatus of claim 1, wherein the fluid cooling assembly comprises plural thermal dissipation plates which are laminated together.

6. The apparatus of claim 5, wherein the plural thermal dissipation plates have features formed thereon by etching or stamping.

7. The apparatus of claim 6, wherein the features formed by etching or stamping comprise at least one of:
an aperture for defining a fluid inlet channel;
a fluid return aperture;
a thermal dissipation fin;
a fluid return region which is substantially surrounded by a lamination rim through which the thermal dissipation plate is in contact with an adjacent thermal dissipation plate.

8. The apparatus of claim 5, wherein collectively the plural thermal dissipation plates define a fluid inlet channel for conveying fluid from the pump to the thermal transfer unit and separately define a fluid return path for conveying fluid from the thermal transfer unit to the pump, and wherein each of the plural thermal dissipation plates have a thermal dissipation fin.

9. The apparatus of claim 5, wherein each of the plural thermal dissipation plates has an aperture for defining a fluid inlet channel through which fluid is communicated from the pump to the thermal transfer unit.

10. The apparatus of claim 5, wherein each of the plural thermal dissipation plates has a fluid return region, the fluid return region comprising a plate floor which is substantially surrounded by a lamination rim through which the thermal dissipation plate is in contact with an adjacent thermal dissipation plate, and wherein a fluid return aperture is formed in the plate floor.

11. The apparatus of claim 10, wherein the plural thermal dissipation plates are stacked in parallel and with a lamination agent positioned on the lamination rims of the plural thermal dissipation plates.

12. The apparatus of claim 10, wherein for two adjacent thermal dissipation plates the fluid return apertures are not aligned in a direction perpendicular to a plane of the thermal dissipation plates.

13. The apparatus of claim 10, wherein each of the plural thermal dissipation plates has an aperture for defining a fluid inlet channel for communicating the fluid from the pump to the thermal transfer unit, the fluid inlet channel extending essentially perpendicularly to parallel planes in which each of the plural thermal dissipation plates substantially lie;
wherein each of the plural thermal dissipation plates has plural fluid return regions;
wherein the fluid inlet channel is positioned centrally with respect to the plural fluid return regions; and,
wherein each laminated plate further comprises a thermal dissipation fin which extends laterally with respect to at least one of the plural fluid return regions.

14. The apparatus of claim 1, wherein the fluid cooling assembly comprises plural thermal dissipation plates which are laminated together, the plural thermal dissipation plates including plural types of thermal dissipation plates, the plural types of dissipation plates being alternately arranged in a laminated stack to provide a non-linear fluid return path to the pump.

15. The apparatus of claim 1, wherein the fluid cooling assembly comprises plural thermal dissipation plates which are laminated together, the plural thermal dissipation plates including a first type thermal dissipation plate and a second type thermal dissipation plate, the first type thermal dissipation plate and the second type thermal dissipation plate being alternately arranged in a laminated stack to provide a non-linear fluid return path to the pump.

16. The apparatus of claim 1, wherein the fluid cooling assembly comprises plural thermal dissipation plates which are laminated together;
wherein each of the plural thermal dissipation plates comprises a thermal dissipation fin; and
wherein the fan directs air around the thermal dissipation fins of the fluid cooling assembly.

17. The apparatus of claim 1, wherein the pump further comprises:
a pump housing;
a piezoelectric diaphragm which serves as an actuator for the pump.

18. The apparatus of claim 1, wherein at least a portion of the fluid cooling assembly is formed from a thermally non-conductive material for thermally isolating the thermal transfer unit from a remainder of the circuit.

19. The apparatus of claim 18, wherein the fluid cooling assembly comprises plural thermal dissipation plates which are laminated together, and wherein one of the plural thermal dissipation plates which is in contact with the thermal transfer unit is formed from a thermally non-conductive material.

20. A thermal exchange system comprising:
a thermal transfer unit for interfacing with a body to be thermally conditioned and for transferring thermal energy to a fluid;
a fluid cooling assembly for cooling the fluid obtained from the thermal transfer unit, the fluid cooling assembly comprising plural thermal dissipation plates which are laminated together;
a fan for directing air around the fluid cooling assembly;
a pump for circulating fluid in a circuit comprising the pump, the thermal transfer unit, and the fluid cooling assembly.

21. The apparatus of claim 20, wherein the thermal transfer unit comprises:
a thermal transfer surface for interfacing with a body to be thermally conditioned; and
a thermal transfer mesh for transferring thermal energy between the thermal transfer surface and a fluid.

22. The apparatus of claim 20, wherein the plural thermal dissipation plates have features formed thereon by etching or stamping.

23. The apparatus of claim 22, wherein the features formed by etching or stamping comprise at least one of:
an aperture for defining a fluid inlet channel;
a fluid return aperture;
a thermal dissipation fin;
a fluid return region which is substantially surrounded by a lamination rim through which the thermal dissipation plate is in contact with an adjacent thermal dissipation plate.

24. The apparatus of claim 21, wherein one of the plural thermal dissipation plates serves as a housing for at least partially enclosing the thermal transfer mesh.

25. The apparatus of claim 20, wherein collectively the plural thermal dissipation plates define a fluid inlet channel for conveying fluid from the pump to the thermal transfer unit and separately define a fluid return path for conveying fluid from the thermal transfer unit to the pump; and wherein each of the plural thermal dissipation plates has a thermal dissipation fin.

26. The apparatus of claim 20, wherein each of the plural thermal dissipation plates has an aperture for defining a fluid inlet channel through which the fluid is communicated from the pump to the thermal transfer unit.

27. The apparatus of claim 20, wherein each of the plural thermal dissipation plates has a fluid return region, the fluid return region comprising a plate floor which is substantially surrounded by a lamination rim through which the thermal dissipation plate is in contact with an adjacent thermal dissipation plate, and wherein a fluid return aperture is formed in the plate floor.

28. The apparatus of claim 27, wherein the plural thermal dissipation plates are stacked in parallel and with a lamination agent positioned on the lamination rims of the plural thermal dissipation plates.

29. The apparatus of claim 27, wherein for two adjacent thermal dissipation plates the fluid return apertures are not aligned in a direction perpendicular to a plane of the thermal dissipation plates.

30. The apparatus of claim 27, wherein each of the plural thermal dissipation plates has an aperture for defining a fluid inlet channel for communicating the fluid from the pump to the thermal transfer unit, the fluid inlet channel extending essentially perpendicularly to parallel planes in which each of the plural thermal dissipation plates substantially lie;
wherein each of the plural thermal dissipation plates has plural fluid return regions; and
wherein the fluid inlet channel is positioned centrally with respect to the plural fluid return regions.

31. The apparatus of claim 30, wherein each laminated plate further comprises a thermal dissipation fin which extends laterally with respect to at least one of the plural fluid return regions.

32. The apparatus of claim 20, wherein the fluid cooling assembly comprises plural thermal dissipation plates which are laminated together, the plural thermal dissipation plates including plural types of thermal dissipation plates, the plural types of dissipation plates being alternately arranged in a laminated stack to provide a non-linear fluid return path to the pump.

33. The apparatus of claim 20, wherein the fluid cooling assembly comprises plural thermal dissipation plates which are laminated together, the plural thermal dissipation plates including a first type thermal dissipation plate and a second type thermal dissipation plate, the first type thermal dissipation plate and the second type thermal dissipation plate being alternately arranged in a laminated stack to provide a non-linear fluid return path to the pump.

34. The apparatus of claim 20, wherein the fluid cooling assembly comprises plural thermal dissipation plates which are laminated together;
wherein each of the plural thermal dissipation plates comprises a thermal dissipation fin; and
wherein the fan directs air around the thermal dissipation fins of the fluid cooling assembly.

35. The apparatus of claim 20, wherein the pump further comprises:
a pump housing;
a piezoelectric diaphragm which serves as an actuator for the pump.

36. The apparatus of claim 20, wherein at least a portion of the fluid cooling assembly is formed from a thermally non-conductive material for thermally isolating the thermal transfer unit from a remainder of the circuit.

37. The apparatus of claim 20, wherein the fluid cooling assembly comprises plural thermal dissipation plates which are laminated together, and wherein one of the plural thermal dissipation plates which is in contact with the thermal transfer unit is formed from a thermally non-conductive material.

38. A thermal exchange system comprising:
a thermal transfer unit for interfacing with a body to be thermally conditioned and for transferring thermal energy to a fluid;
a fluid cooling assembly for cooling the fluid obtained from the thermal transfer unit;
a fan for directing air around the fluid cooling assembly;
a pump for circulating fluid in a circuit comprising the pump, the thermal transfer unit, and the fluid cooling assembly; and
wherein the fluid cooling assembly is in direct contact with the thermal transfer unit and thermally isolates the thermal transfer unit from a remainder of the circuit.

39. The apparatus of claim 38, wherein at least a portion of the fluid cooling assembly is formed from a thermally non-conductive material.

40. The apparatus of claim 38, wherein the fluid cooling assembly comprises plural thermal dissipation plates which are laminated together, and wherein one of the plural thermal dissipation plates which is in contact with the thermal transfer unit is formed from a thermally non-conductive material.

41. A method of making a thermal exchange system, the method comprising:
laminating plural thermal dissipation plates for forming a fluid cooling assembly;
connecting the fluid cooling assembly between a pump and a thermal transfer unit for forming a fluid circuit.

42. The method of claim 41, wherein the thermal transfer unit comprises:
a thermal transfer surface for interfacing with a body to be thermally conditioned; and
a thermal transfer mesh for transferring thermal energy between the thermal transfer surface and a fluid, and wherein the method further comprises:
forming one of the plural thermal dissipation plates for serving as a housing for at least partially enclosing the thermal transfer mesh.

43. The method of claim 41, further comprising etching or stamping a feature on the plural thermal dissipation plates.

44. The method of claim 43, wherein the feature formed by etching or stamping comprise at least one of:
an aperture for defining a fluid inlet channel;
a fluid return aperture;
a thermal dissipation fin;
a fluid return region which is substantially surrounded by a lamination rim through which the thermal dissipation plate is in contact with an adjacent thermal dissipation plate.

45. The method of claim 41, further comprising:
forming each of the plural thermal dissipation plates with a lamination contact surface;
stacking the plural thermal dissipation plates in parallel and with a lamination agent positioned on the lamination contact surfaces of the plural thermal dissipation plates;
curing the lamination agent to form a modular fluid cooling assembly.

46. A pump comprising:
a pump body having a rim for defining a pump chamber and a body floor interior of the rim, the body floor having at least one fluid flow feature provided therein;
a flexible valve layer residing above the body floor and having a valve flap for selectively covering and opening the fluid flow feature provided in the body floor;
a pump chamber insert for fitting over the valve layer and sandwiching the valve layer between the pump chamber insert and the body floor, the pump chamber insert having an aperture therein for communicating fluid to the fluid flow feature in accordance with covering and opening of the fluid flow feature by the valve flap;
a diaphragm layer which covers the pump chamber insert for defining a pump chamber between the diaphragm and the pump chamber insert.
